(19) United States
(12) Patent Application Publication
(10) Pub. No.: US 2025/0201525 A1
(43) Pub. Date: Jun. 19, 2025

(54) SUBSTRATE PROCESSING APPARATUS AND SUBSTRATE PROCESSING METHOD

(71) Applicant: SEMES CO., LTD., Cheonan-si (KR)

(72) Inventor: Jinhyeok KIM, Pohang-si (KR)

(21) Appl. No.: 18/968,035

(22) Filed: Dec. 4, 2024

(30) Foreign Application Priority Data
Dec. 14, 2023 (KR) 10-2023-0182144

(51) Int. Cl. H01J 37/32; H01L 21/311; H01L 21/66

(52) U.S. Cl. CPC H01J 37/32449; H01J 37/32963; H01L 21/31116; H01L 22/26; H01J 2237/24585; H01J 2237/334

(57) ABSTRACT

Provided is a substrate processing method for processing a substrate including a multilayer formed by alternately and repeatedly depositing first and second layers of different materials, the substrate processing method including alternately and repeatedly performing a first process step for plasma-etching a first layer by injecting a first process gas into a chamber of a substrate processing apparatus, and a second process step for plasma-etching a second layer by injecting a second process gas into the chamber, as a unit two or more times, wherein, when switching between the first and second process steps, a ramping period in which flow rates of the first and second process gases are gradually changed is provided.

### CROSS-REFERENCE TO RELATED PATENT APPLICATION

This application claims the benefit of Korean Patent Application No. 10-2023-0182144, filed on Dec. 14, 2023, in the Korean Intellectual Property Office, the disclosure of which is incorporated herein in its entirety by reference.

### BACKGROUND OF THE INVENTION

### 1. Field of the Invention

The present invention relates to a substrate processing apparatus and a substrate processing method and, more particularly, to a substrate processing apparatus for performing a cyclic etching process using plasma, and a substrate processing method using the same.

### 2. Description of the Related Art

Currently, semiconductor systems are pursuing high capacity and high functionality due to high integration of semiconductor elements and increase in size of semiconductor substrates. Because integration of more elements within a limited area is required accordingly, the semiconductor systems are being studied and developed to achieve ultra-fineness and high integration of desired patterns.

A substrate processing apparatus includes a dry etching apparatus for activating and transforming a reaction gas to a plasma status in a process chamber to allow cations or radicals of the reaction gas in the plasma status to etch a certain area of a semiconductor substrate. Depending on a method of generating plasma, the plasma is divided into capacitively coupled plasma (CCP), inductively coupled plasma (ICP), electron cyclotron resonance (ECR) plasma and surface wave plasma (SWP) using microwaves, etc. For the CCP type, the reaction gas is transformed to a plasma status by an electric field formed by selectively applying high-frequency radio-frequency (RF) power to a plurality of electrodes mounted in the process chamber. For the ICP type, the reaction gas is transformed to a plasma status by a magnetic or electric field formed by applying high-frequency RF power to a coil wound outside the process chamber.

A substrate processing method may include an etching process for etching a material deposited on at least one surface of a substrate, by using plasma. The material to be etched includes a multilayer formed by alternately depositing different materials. For example, FIG. 7 shows a multilayer 700 as a structure to be etched. Referring to FIG. 7, the multilayer 700 may be a structure in which silicon oxide layers are deposited as first layers 710, and silicon nitride layers are deposited as second layers 720 on the first layers 710. Two or more, e.g., dozens or more of, first and second layers 710 and 720 may be alternately and repeatedly deposited to form the multilayer 700.

When two or more first and second layers 710 and 720 of different materials are alternately deposited, the etching process is performed under different process conditions by material. For example, when both of first and second layers in the multilayer structure illustrated in FIG. 7 need to be etched, a process for etching a silicon oxide layer deposited as the first layer and a process for etching a silicon nitride layer deposited as the second layer use different process gases. Therefore, due to the different process gases, switching of etching processes occurs after a process step for etching each layer is completed. When switching etching processes, the type of etching gas supplied into a process chamber of a substrate processing apparatus needs to be changed. Because the first and second layers are repeatedly and alternately deposited in the multilayer, the etching processes also need to be repeatedly and alternately switched. An etching process in which a cycle including a first process step for etching a first layer and a second process step for etching a second layer is repeated a plurality of times as described above is referred to as a cyclic etching process.

In the cyclic etching process, because the etching gas supplied to the substrate processing apparatus is rapidly changed while switching process steps, a process pressure inside the process chamber may not be stabilized and have an instable status after switching process steps. When a long time is taken to stabilize the process pressure after switching process steps, it may affect etching process stability and thus the etching process instability may adversely affect the quality of semiconductor devices.

### SUMMARY OF THE INVENTION

The present invention provides a substrate processing method capable of reducing changes in pressure inside a process chamber and a process stabilization time when switching process steps, and a substrate processing apparatus capable of performing the same. However, the above description is an example, and the scope of the present invention is not limited thereto.

According to an aspect of the present invention, there is provided a substrate processing method for processing a substrate including a multilayer formed by alternately and repeatedly depositing first and second layers of different materials, the substrate processing method including alternately and repeatedly performing a first process step for plasma-etching a first layer by injecting a first process gas into a chamber of a substrate processing apparatus, and a second process step for plasma-etching a second layer by injecting a second process gas into the chamber, as a unit two or more times, wherein, when switching between the first and second process steps, a ramping period in which flow rates of the first and second process gases are gradually changed is provided.

The ramping period may include a first ramping period in which the flow rate of the first process gas is gradually increased and the flow rate of the second process gas is correspondingly gradually reduced, and a second ramping period in which the flow rate of the first process gas is gradually reduced and the flow rate of the second process gas is correspondingly gradually increased.

A reduction start point of the flow rate of the first process gas may be synchronized with an increase start point of the flow rate of the second process gas, and an increase start point of the flow rate of the first process gas may be synchronized with a reduction start point of the flow rate of the second process gas.

A process pressure of the first process step and a process pressure of the second process step may have the same set value.

The substrate processing method may further include measuring a chamber pressure in real time in the ramping period, and controlling the flow rates of the first and second process gases supplied to the chamber in the ramping period, in real time to correspond to the measured chamber pressure.

The ramping period may include a period in which speeds of supplying the first and second process gases are different from each other.

The first layers may include silicon oxide layers, and the second layers may include silicon nitride layers.

Each of the first and second process steps may include a ramping up period in which a flow rate of a process gas is gradually increased, a period in which the flow rate of the process gas is constantly maintained, and a ramping down period in which the flow rate of the process gas is gradually reduced.

The ramping up period of the first process step and the ramping down period of the second process step may overlap each other, or the ramping down period of the first process step and the ramping up period of the second process step may overlap each other.

The first and second process steps may have different conditions of plasma generation power and, when switching between the first and second process steps, the plasma generation power may be gradually changed in the ramping period.

A speed of changing the plasma generation power in the ramping period may be associated with a speed of changing the flow rate of the first or second process gas in the ramping period.

The ramping period may include a period in which speeds of changing the plasma generation power are different from each other.

The switching between the first and second process steps may include detecting an end point of one of the first and second process steps, gradually reducing a flow rate of a process gas used for a process step, the end point of which is detected, while gradually increasing a flow rate of a process gas used for a process step other than the process step, the end point of which is detected, and maintaining the flow rate of the process gas used for the process step other than the process step, the end point of which is detected, at a set value at a point of time when supply of the process gas used for the process step, the end point of which is detected, is cut off.

The detecting of the end point may include detecting the end point by analyzing by-products of etching produced during the process step by using an optical emission spectroscope (OES) connected to the substrate processing apparatus.

According to another aspect of the present invention, there is provided a substrate processing apparatus for processing a substrate including a multilayer formed by alternately and repeatedly depositing first and second layers of different materials, the substrate processing apparatus including a chamber having an internal space where plasma is generated, and including a substrate supporter in the internal space to support the substrate, a gas supplier for supplying a first process gas for etching the first layers, and a second process gas for etching the second layers, to the substrate, a high-frequency power source for applying high-frequency power into the chamber to excite the first or second process gas into plasma, and a controller for controlling flow rates of the first and second process gases, wherein the controller controls the flow rates of the first and second process gases to be gradually changed in a ramping period in which switching occurs between a first process step for etching a first layer and a second process step for etching a second layer.

The substrate processing apparatus may further include an end point detector (EPD) for detecting an end point of a process step by analyzing by-products of etching produced in the internal space.

The substrate processing apparatus may further include a pressure sensor for measuring a pressure inside the chamber, and the controller may receive the measured pressure inside the chamber from the pressure sensor in real time, and control the flow rates of the first and second process gases in the ramping period in real time based on the pressure inside the chamber.

The controller may control plasma generation power to be gradually changed between the first and second process steps in the ramping period.

The controller may control the plasma generation power in real time in association with changes in flow rates of the first and second process gases.

According to another aspect of the present invention, there is provided a substrate processing apparatus for processing a substrate including a multilayer formed by alternately and repeatedly depositing first and second layers of different materials, the substrate processing apparatus including a chamber having an internal space where plasma is generated, and including a substrate supporter in the internal space to support the substrate, a gas supplier for supplying a first process gas for etching the first layers, and a second process gas for etching the second layers, to the substrate, a high-frequency power source for applying high-frequency power into the chamber to excite the first or second process gas into plasma, an end point detector (EPD) for detecting an end point of a process step by analyzing by-products of etching produced in the chamber, a vent line connected to a vent hole provided in a portion of the chamber to discharge internal gas, and having an automatic pressure controller (APC) valve and a pressure sensor mounted thereon, and a controller for receiving a measured chamber pressure from the pressure sensor in real time in a ramping period in which switching occurs between a first process step for etching a first layer and a second process step for etching a second layer, controlling flow rates of the first and second process gases in the ramping period in real time based on the chamber pressure, and controlling plasma generation power to be gradually changed between the first and second process steps in real time in association with changes in flow rates of the first and second process gases in the ramping period.

### BRIEF DESCRIPTION OF THE DRAWINGS

The above and other features and advantages of the present invention will become more apparent by describing in detail embodiments thereof with reference to the attached drawings in which:

FIG. 1 is a schematic view of a substrate processing apparatus for performing a cyclic etching process;

FIG. 2 is a graph showing changes in flow rates of etching gases supplied into a chamber of a substrate processing apparatus to etch first and second layers of a multilayer, over time;

FIG. 3 is a graph showing a result of measuring changes in actual process pressure inside a chamber when switching process steps in a case in which the process pressure is maintained at 20 mT in a first process step and at 10 mT in a second process step of FIG. 2;

FIG. 4 is a graph showing a result of measuring changes in process pressure inside a chamber when switching process steps in a case in which the process pressure is set to be the same in all process steps;

FIG. 5 is a graph for describing a method of controlling the supply of process gases during a cyclic etching process, according to an embodiment of the present invention;

FIG. 6 is a graph for describing a method of controlling the supply of process gases during a cyclic etching process, according to an embodiment of the present invention; and

FIG. 7 is a cross-sectional view of a multilayer structure to be etched.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

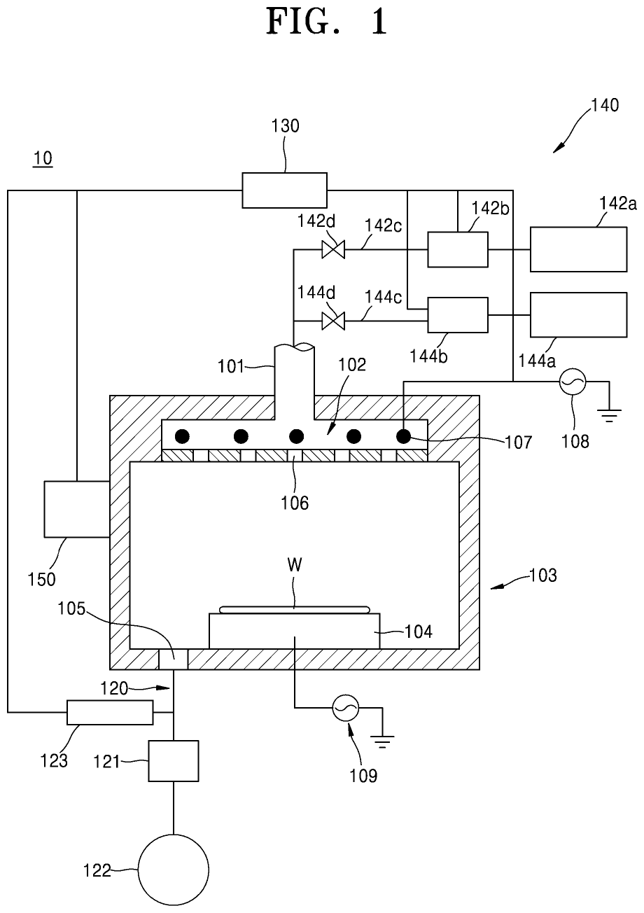

FIG. 1 is a schematic view of a substrate processing apparatus 10 for performing a cyclic etching process.

Referring to FIG. 1, the substrate processing apparatus 10 includes a chamber 103 having an internal space where plasma is generated. A substrate supporter 104 is included in the internal space of the chamber 103. The substrate supporter 104 may be located at the bottom of the chamber 103 to support a substrate W.

A gas supplier 140 serves to supply process gases required for etching processes, into the chamber 103 through a gas inlet 101 provided on the chamber 103, and includes gas storages 142a and 144a, transfer lines 142c and 144c for transferring the process gases from the gas storages 142a and 144a to the chamber 103, mass flow controllers (MFCs) 142b and 144b for controlling flow rates of the process gases flowing through the transfer lines 142c and 144c, and valves 142d and 144d capable of opening or closing the transfer lines 142c and 144c to transfer the process gases.

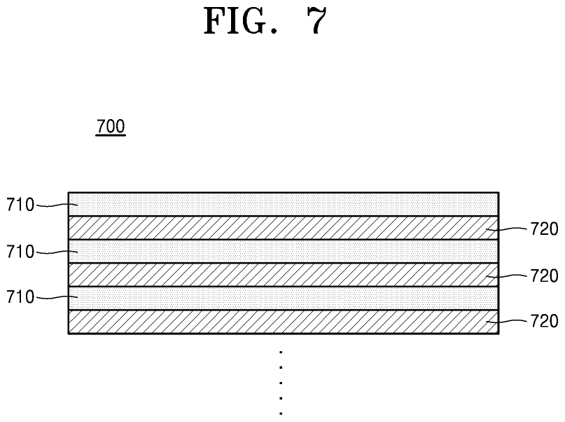

For example, the gas supplier 140 of FIG. 1 is provided to supply a first process gas for etching silicon oxide layer, and a second process gas for etching silicon nitride layer, as process gases for etching the multilayer 700 illustrated in FIG. 7. Herein, the first process gas is a gas for etching silicon oxide layer and may refer to a gas mixture in which a plurality of gases with different chemical formulas are mixed. The second process gas is a gas for etching silicon nitride layer and may refer to a gas mixture in which a plurality of gases with different chemical formulas are mixed.

Specifically, the gas supplier 140 includes a first process gas storage 142a storing the first process gas, a first transfer line 142c for transferring the first process gas, a first MFC 142b for controlling a flow rate of the first process gas, and a first process gas supply valve 142d capable of opening or closing the first transfer line 142c to transfer the first process gas. The gas supplier 140 further includes a second process gas storage 144a storing the second process gas, a second transfer line 144c for transferring the second process gas, a second MFC 144b for controlling a flow rate of the second process gas, and a second process gas supply valve 144d capable of opening or closing the second transfer line 144c to transfer the second process gas.

A gas injector 102 is a structure provided with a plurality of injection holes 106 through which a process gas supplied from the gas supplier 140 to the chamber 103 through the gas inlet 101 may pass, to uniformly supply the process gas onto the substrate W, and is disposed above the substrate W.

To generate plasma from the process gas supplied into the chamber 103, a spiral antenna 107 for supplying power is disposed at the top of the chamber 103. A first high-frequency power source 108 is connected to the antenna 107. The first high-frequency power source 108 includes a radio-frequency (RF) power source. After the process gas is supplied into the chamber 103, when high-frequency power is applied from the first high-frequency power source 108 to the antenna 107, electromagnetic waves generated from the antenna 107 are supplied into the chamber 103 to excite the process gas to a plasma status.

The substrate supporter 104 may serve to adsorb or release the substrate W onto or from a dielectric surface by controlling electrostatic force generated due to dielectric polarization by electrodes provided therein. To apply a negative bias to the substrate W, a second high-frequency power source 109 for applying high-frequency power may be connected to the substrate supporter 104. However, the substrate W is not limited thereto, and may also be held by a mechanical clamp, a vacuum chuck, or the like.

The substrate processing apparatus 10 includes a vent hole 105 provided in a portion of the chamber 103 to discharge internal gas, and a vent line 120 connected to the vent hole 105 and having an automatic pressure controller (APC) valve 121 mounted thereon. A pressure sensor 123 for measuring a pressure inside the chamber 103 is mounted on the vent line 120. The vent line 120 may be connected to a vacuum pump 122 to serve as a path through which by-products produced in the internal space of the chamber 103 are discharged to the outside of the chamber 103, or to form a vacuum in the internal space.

The APC valve 121 is a valve for adjusting the pressure inside the chamber 103, and the pressure inside the chamber 103 is adjusted by controlling the opening or closing of the APC valve 121 based on the pressure inside the chamber 103 measured by the pressure sensor 123 while the vacuum pump 122 is operating. A degree of the opening or closing of the APC valve 121 may be expressed by an APC position. The APC position may be expressed as 1 when the APC valve 121 is fully open, or 0 when the APC valve 121 is fully closed. Therefore, when the APC position is increased while the vacuum pump 122 is operating, it means that the APC valve 121 opens and thus the amount of exhaust gas discharged from the chamber 103 is increased. When the APC position is reduced, it means the opposite. When a value of the pressure of the chamber 103 is set, the pressure inside the chamber 103 may be adjusted to the set value by automatically adjusting the opening or closing of the APC valve 121 by reflecting the pressure of the chamber 103 measured by the pressure sensor 123.

An end point detector (EPD) 150 for detecting a reaction occurring inside the chamber 103 in real time to detect an end point of the reaction is coupled to the substrate processing apparatus 10. The EPD 150 includes an optical emission spectrometer (OES), and may detect environmental changes inside the chamber 103, e.g., changes in contents (or partial pressures) of reaction gases due to a reaction therebetween, and production of by-products of reaction, in real time by analyzing peaks measured by the OES.

The reaction occurring inside the chamber 103 includes a reaction occurring during etching. For example, when the first layers 710 such as silicon oxide layers and the second layers 720 such as silicon nitride layers are alternately deposited as shown in FIG. 7, by-products of etching may be analyzed while a silicon oxide layer is being etched, and thus a moment when the etching of the silicon oxide layer ends to expose a silicon nitride layer may be detected. That is, when the silicon oxide layer is completely etched to expose the silicon nitride layer thereunder, by-products of the silicon oxide layer are no longer produced. As such, it may be determined that the etching of the silicon oxide layer is completed, and this point of time is detected as an end point of the etching of the silicon oxide layer. The above description is equally applied to the silicon nitride layer. Therefore, using the EPD 150, a point of time when the silicon oxide etching step is switched to the silicon nitride etching step (or vice versa) may be checked in real time.

To perform a cyclic etching process using the substrate processing apparatus 10 of FIG. 1, different etching gases need to be alternately supplied in different process steps of etching. A method of performing a cyclic etching process on the multilayer 700 illustrated in FIG. 7 will now be described.

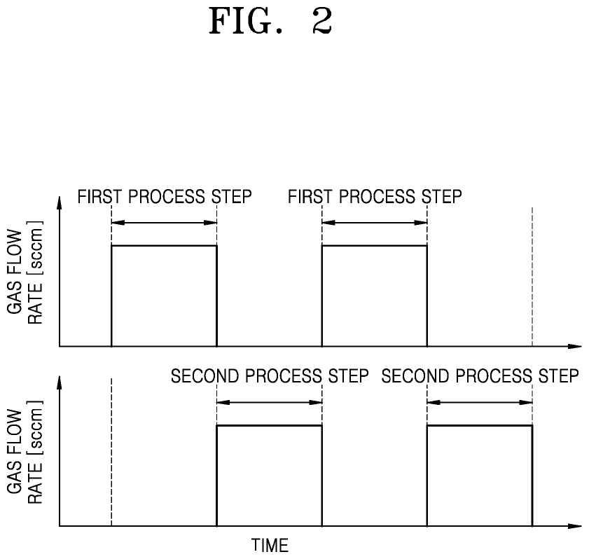

FIG. 2 is a graph showing changes in flow rates of process gases supplied into the chamber 103 of the substrate processing apparatus 10 to etch the first and second layers 710 and 720 of the multilayer 700, over time. In FIG. 2, a first process step is a step for supplying a first process gas such as a silicon oxide etching gas to etch a first layer 710 provided as a silicon oxide layer, and a second process step is a step for supplying a second process gas such as a silicon nitride etching gas to etch a second layer 720 provided as a silicon nitride layer.

Referring to FIG. 2, in the first process step, the first process gas for etching silicon oxide layer is supplied at a first flow rate. When the first process step is completed, the supply of the first process gas is cut off and instead, the second process gas is supplied at a second flow rate to perform the second process step. When the second process step is completed, the first process gas is supplied at the first flow rate to perform the first process step again, and then the second and first process steps are alternately repeated.

When the flow rate of the etching gas supplied to the chamber 103 is intermittently and rapidly changed to switch process steps in the cyclic etching process as shown in FIG. 2, a process pressure inside the chamber 103 may not be promptly stabilized but remain unstable for a considerably long time after switching process steps. When a long time is taken to stabilize the process pressure after switching process steps, it may affect etching process stability and thus the etching process instability may adversely affect the quality of semiconductor devices. Particularly, when a difference in process pressure occurs due to a difference in flow rate of a process gas inserted into the chamber 103 between process steps, pressure stabilization after switching process steps may become more difficult.

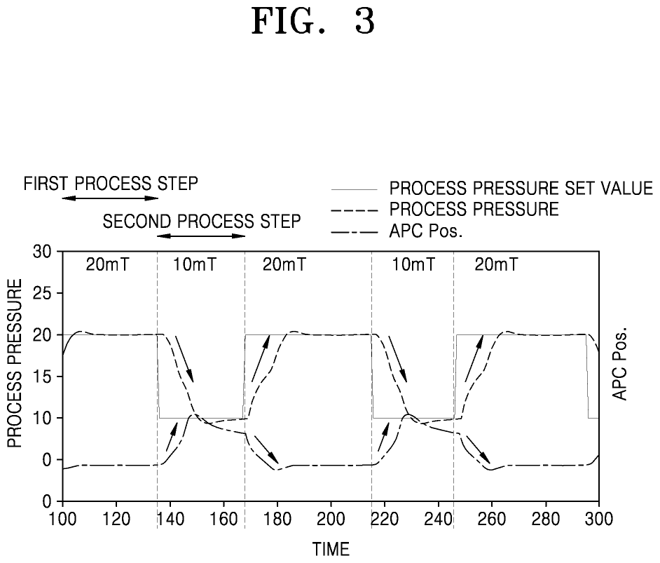

FIG. 3 is a graph showing a result of measuring changes in actual process pressure inside the chamber 103 when switching process steps in a case in which the process pressure is maintained at 20 mT in the first process step and at 10 mT in the second process step of FIG. 2.

Referring to FIG. 3, when switching from the first process step in which the process pressure is maintained at 20 mTorr to the second process step in which the process pressure is maintained at 10 mTorr, to reduce the process pressure inside the chamber 103, the amount of gas discharged through the vacuum pump 122 is increased by opening the APC valve 121. APC Pos. in the graph of FIG. 3 indicates the position of the APC valve 121, and an increase in APC Pos. indicates that the APC valve 121 is opened to increase the amount of exhaust gas passing through the APC valve 121, while a reduction in APC Pos. indicates that the APC valve 121 is closed to reduce the amount of exhaust gas passing through the APC valve 121.

Referring to FIGS. 2 and 3, it is shown that, when process steps are performed at different process pressures, because the APC valve 121, which is an automatic pressure valve, is not rapidly opened or closed in response to an intermittent change of a process gas supplied to the chamber 103 to switch process steps, a target process pressure is not rapidly reached and instability is caused after switching process steps. To ensure excellent etching characteristics in a cyclic etching process, changes in process pressure occurring when switching process steps need to be minimized and the process pressure needs to be stabilized to a target value as rapidly as possible.

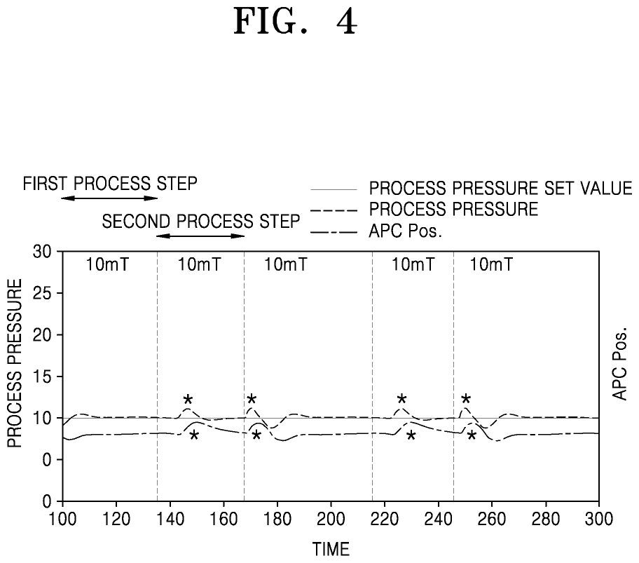

FIG. 4 is a graph showing a result of measuring changes in process pressure inside the chamber 103 when switching process steps in a case in which the process pressure is equally set to be 10 mT in both of the first and second process steps to solve the problems caused when the process pressures of the process steps are different. Referring to FIG. 4, even when the pressures of all process steps are maintained the same, instantaneous fluctuations of the process pressure are observed after switching process steps (as indicated by * in FIG. 4).

It is regarded that the fluctuations shown in FIG. 4 are caused by the difference between process conditions of the first and second process steps. The process conditions may include plasma generation power applied to excite a process gas into plasma. For example, the plasma generation power in the first process step may have a higher value than the plasma generation power in the second process step. In this case, when switching process steps, although the process pressure is set to be the same value, instant changes in actual process pressure inside the chamber 103 may be induced due to a rapid switching of the plasma generation power applied to the process gas.

The present invention provides a substrate processing method capable of minimizing the instability of the pressure inside the chamber 103 when switching process steps in a cyclic etching process, and of reducing a time taken for process stabilization.

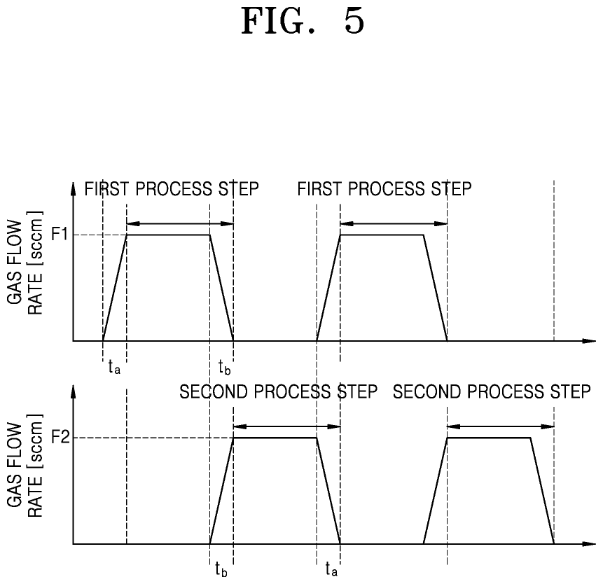

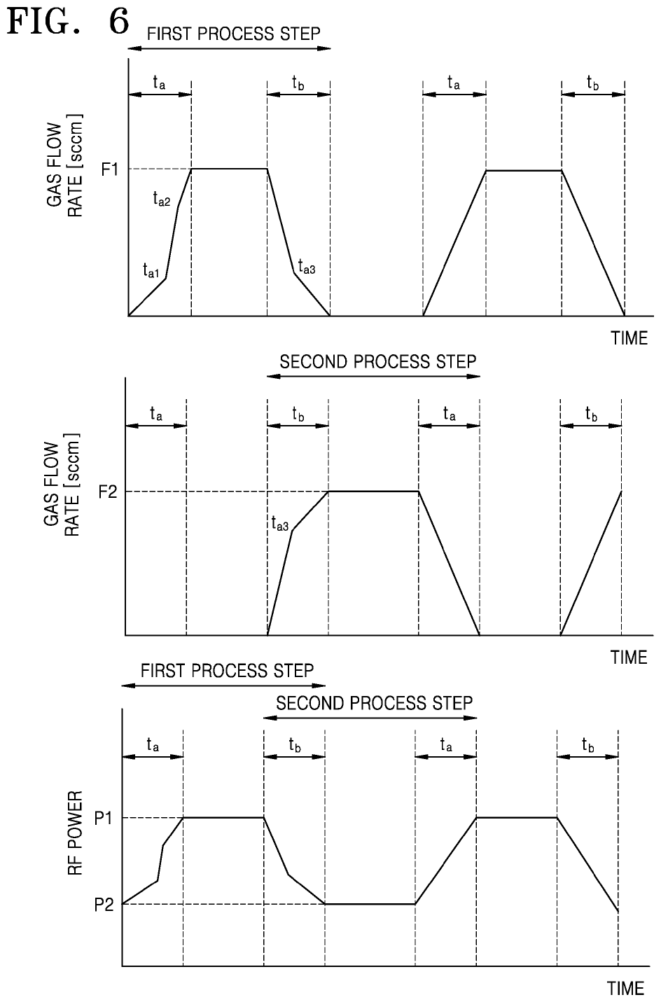

A substrate processing method according to an embodiment of the present invention will now be described in detail with reference to FIGS. 5 and 6.

The present invention provides a method capable of minimizing changes in process pressure when switching process steps in a cyclic etching process, and of stabilizing the process pressure as rapidly as possible.

FIG. 5 is a graph for describing a method of controlling the supply of process gases during a cyclic etching process, according to an embodiment of the present invention.

Referring to FIG. 5, flow rates of the process gases are controlled to be gradually increased or reduced when switching process steps. In this case, the process pressures of all process steps are maintained the same.

Specifically, a first process gas is supplied into the chamber 103 to perform a first process step, and a flow rate of the first process gas is controlled to be gradually increased to a set value F1 of gas flow rate during a certain period of time tₐ. Referring to FIG. 1, the controller 130 of the substrate processing apparatus 10 controls the first MFC 142b to control the flow rate of the first process gas supplied from the first process gas storage 142a to the chamber 103 to be gradually increased from a point of time when the first process gas is supplied. When a pressure inside the chamber 103 is stabilized, the first process step may be performed. The stabilization of the pressure inside the chamber 103 during a process step is achieved by operation of the APC valve 121 based on a pressure value measured by the pressure sensor 123.

While the first process step is being performed, the EPD 150 detects an end point of the first process step by analyzing by-products of etching during the first process step in real time. The controller 130 receives end point detection information from the EPD 150, gradually reduces the flow rate of the first process gas during a certain period of time t_{b}, and ultimately cuts off the supply of the first process gas to terminate the first process step.

The controller 130 supplies a second process gas into the chamber 103 to switch to a second process step at a point of time the same as the point of time when the first process gas is reduced, and controls a flow rate of the second process gas to be gradually increased to a set value F2 of gas flow rate during a certain period of time t_{b} from the point of time when the second process gas is supplied.

As shown in FIG. 5, flow rate reduction start and end points of the first process gas during the first process step are synchronized with flow rate increase start and end points of the second process gas during the second process step. Therefore, when switching from the first process step to the second process step, the period of time t_{b} between process gas flow rate reduction start and end points of the first process step is the same as the period of time t_{b} between process gas flow rate increase start and end points of the second process step.

While the second process step is being performed, the EPD 150 detects an end point of the second process step in the same manner as the first process step, and the controller 130 terminates the second process step and switches to the first process step in the same manner as the above-described method. When switching from the second process step to the first process step, the period of time tₐ between process gas flow rate reduction start and end points of the second process step is the same as the period of time tₐ between process gas flow rate increase start and end points of the first process step. As shown in FIG. 5, flow rate reduction start and end points of the second process gas during the second process step are synchronized with flow rate increase start and end points of the first process gas during the first process step.

A flow rate increase or reduction period of the first process gas and a flow rate reduction or increase period of the second process gas overlap each other when switching process steps, and a sum of the flow rates of the first and second process gases may be maintained at a constant value. To this end, the controller 130 may control the flow rates of the first and second process gases by process step. To constantly maintain the pressure inside the chamber 103 while switching process steps, the opening or closing of the APC valve 121 is controlled based on a pressure value measured by the pressure sensor 123.

A period in which a process gas supplied in a process step is increased or reduced is defined as a ramping period. The process step includes a ramping up period in which a flow rate of the process gas is gradually increased, a period in which the flow rate of the process gas is constantly maintained, and a ramping down period in which the flow rate of the process gas is gradually reduced. In a period in which the flow rate of the first process gas is reduced in the first process step, a speed at which the flow rate is reduced is referred to as a ramping down speed and defined as a value obtained by dividing the flow rate change F1 by the period of time to. In the same manner, a ramping up speed in the first process step is defined as a value obtained by dividing the flow rate change F1 by the period of time tₐ, a ramping down speed in the second process step is defined as a value obtained by dividing the flow rate change F2 by the period of time tₐ, and a ramping up speed in the second process step is defined as a value obtained by dividing the flow rate change F2 by the period of time t_{b}.

In the current embodiment, the ramping up speed and the ramping down speed of the first and second process steps are maintained at constant values.

According to the current embodiment, unlike the illustration of FIG. 2, when switching process steps, periods in which the first and second process gases are gradually changed overlap each other and process gas supply amounts are gradually changed. Therefore, the instability of the pressure inside the chamber 103 after switching process steps due to rapid changes as shown in FIG. 2 may be solved, and a time taken for process stabilization may be reduced. The rapid pressure stabilization when switching process steps contributes to increasing the quality of etching.

FIG. 6 is a graph for describing a method of controlling the supply of process gases during a cyclic etching process, according to an embodiment of the present invention. The current embodiment is different from the previous embodiment described above with reference to FIG. 5 in that a ramping up speed or a ramping down speed in a ramping period is not fixed to a constant value but is controlled in real time. An embodiment of the present invention will now be described in detail with reference to FIG. 6.

According to the current embodiment, a pressure inside the chamber 103 is measured using the pressure sensor 123 in real time while a process gas is being increased or reduced when switching process steps. When it is determined based on the measurement result that the pressure inside the chamber 103 is out of a preset target value, a flow rate of the process gas supplied from the gas supplier 140 into the chamber 103 is controlled in real time. As such, the ramping up speed or the ramping down speed in the ramping period may be changed to another value in the period without being constantly maintained.

To this end, referring to FIG. 1, the controller 130 determines whether the pressure inside the chamber 103 (or chamber pressure) received from the pressure sensor 123 is different from a set value, and controls the flow rate of the supplied process gas by controlling the MFC 142b or 144b until the actually measured chamber pressure is the same as the set value, when the chamber pressure is different from the set value.

Referring to FIG. 6, specifically, a first process gas is supplied into the chamber 103 to perform a first process step, and a flow rate of the first process gas is controlled to be gradually increased to a set value F1 of gas flow rate during a certain period of time ta.

Referring to FIG. 1, the pressure sensor 123 measures and transmits the chamber pressure to the controller 130 in real time while the flow rate of the first process gas is being increased. When it is determined that the receive chamber pressure is lower than a set value, the controller 130 starts to increase a speed of supplying the first process gas by controlling the first MFC 142b (point of time tₐ₁). Thereafter, when it is determined that the chamber pressure value received from the pressure sensor 123 is higher than the set value, the controller 130 starts to reduce the speed of supplying the first process gas by controlling the first MFC 142b again (point of time tₐ₂). When the flow rate of the first process gas ultimately reaches the set value F1 of the first process step, the controller 130 controls the first MFC 142b to maintain the flow rate corresponding to the set value F1.

While the first process step is being performed, the EPD 150 detects an end point of the first process step by analyzing by-products of etching during the first process step in real time. The controller 130 receives end point detection information from the EPD 150, gradually reduces the flow rate of the first process gas during a certain period of time t_{b}, and ultimately cuts off the supply of the first process gas to terminate the first process step. The pressure sensor 123 measures and transmits the chamber pressure to the controller 130 in real time while the flow rate of the first process gas is being reduced. When the received chamber pressure value is different from a set value, the controller 130 correspondingly controls the first MFC 142b to change the speed of supplying the first process gas (point of time tₐ₃). The controller 130 ultimately cuts off the supply of the first process gas to terminate the first process step.

The controller 130 supplies a second process gas into the chamber 103 to switch to a second process step at a point of time the same as the point of time when the first process gas is reduced, and controls a flow rate of the second process gas to be gradually increased to a set value F2 of gas flow rate during a certain period of time to from the point of time when the second process gas is supplied. The pressure sensor 123 measures and transmits the chamber pressure to the controller 130 in real time while the flow rate of the second process gas is being increased. When the received chamber pressure value is different from a preset target value, the controller 130 correspondingly controls the second MFC 144b to change a speed of supplying the second process gas (point of time tₐ₃). When the flow rate of the second process gas ultimately reaches the set value F2 of the second process step, the controller 130 controls the second MFC 144b to maintain the flow rate corresponding to the set value F2.

When an end point of the second process step is received from the EPD 150, the controller 130 gradually reduces the flow rate of the second process gas while gradually increasing the flow rate of the first process gas in the same manner as the above-described method. When the chamber pressure measured by the pressure sensor 123 in real time in the ramping period is not different from a reference value, the speeds of supplying the first and second process gases are maintained without being changed during the ramping period.

That is, according to the current embodiment, as shown in FIG. 6, a chamber pressure is measured in real time in a ramping period, and speeds of supplying process gases are changed in real time based on the real-time measured chamber pressure value. Therefore, instable changes in chamber pressure while switching process steps may be prevented, and rapid process stabilization may be achieved.

Additionally, changes in plasma generation power may be controlled in synchronization with the changes in flow rates of process gases. Referring to FIG. 6, it is shown that plasma generation power (indicated as RF power in FIG. 6) is also changed in association with the changes in flow rates of process gases in ramping periods of the first and second process steps.

The plasma generation power is changed as described above in order to prevent changes in process pressure, which instantaneously occur as shown in FIG. 4 due to the difference in plasma generation power between process steps even when the same process pressure is set for all process steps, as much as possible.

Referring to FIG. 6, a set value of plasma generation power in the first process step is P1, and a set value of plasma generation power in the second process step is P2. The plasma generation power is reduced from P1 to P2 when switching from the first process step to the second process step, and increased from P2 to P1 when switching from the second process step to the first process step. When switching the plasma generation power from P1 to P2 or from P2 to P1, like the switching of process gases, a ramping period tₐ or t_{b} in which the plasma generation power is gradually reduced or increased is provided.

Referring to FIGS. 1 and 6, the controller 130 controls the first high-frequency power source 108 to change a speed of increasing the plasma generation power applied to the antenna 107, at points of time tₐ₁ and tₐ₂ when the speed of supplying the first process gas is changed in the ramping up period tₐ of the first process step. The above description is equally applied to the ramping down period t_{b} of the first process step. When a speed of supplying a process gas is not changed in a ramping period of a process step, the speed of increasing or reducing the plasma generation power applied to the antenna 107 may be maintained without being changed.

According to the current embodiment, in a cyclic etching process, process gases may be gradually switched when repeatedly switching process steps and, particularly, changes in pressure of the chamber 103 in a ramping period may be measured in real time and speeds of changing flow rates of the process gases and a speed of applying plasma generation power in the ramping period may be changed in real time based on the measured pressure value, thereby preventing process pressure instability occurring when switching process steps, greatly reducing a time taken for process stabilization, and ultimately achieving excellent etching characteristics.

According to the afore-described embodiments of the present invention, by controlling changes in flow rates of etching gases supplied to a process chamber and changes in plasma generation power when switching process steps, in real time based on changes in process pressure inside the process chamber, the pressure inside the chamber may be rapidly stabilized to achieve etching process stabilization and increase in quality of semiconductor devices. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A substrate processing method for processing a substrate comprising a multilayer formed by alternately and repeatedly depositing first and second layers of different materials, the substrate processing method comprising alternately and repeatedly performing a first process step for plasma-etching a first layer by injecting a first process gas into a chamber of a substrate processing apparatus, and a second process step for plasma-etching a second layer by injecting a second process gas into the chamber, as a unit two or more times,
wherein, when switching between the first and second process steps, a ramping period in which flow rates of the first and second process gases are gradually changed is provided.

2. The substrate processing method of claim 1, wherein the ramping period comprises:
a first ramping period in which the flow rate of the first process gas is gradually increased and the flow rate of the second process gas is correspondingly gradually reduced; and
a second ramping period in which the flow rate of the first process gas is gradually reduced and the flow rate of the second process gas is correspondingly gradually increased.

3. The substrate processing method of claim 2, wherein a reduction start point of the flow rate of the first process gas is synchronized with an increase start point of the flow rate of the second process gas, and
wherein an increase start point of the flow rate of the first process gas is synchronized with a reduction start point of the flow rate of the second process gas.

4. The substrate processing method of claim 1, wherein a process pressure of the first process step and a process pressure of the second process step have the same set value.

5. The substrate processing method of claim 1, further comprising:
measuring a chamber pressure in real time in the ramping period; and
controlling the flow rates of the first and second process gases supplied to the chamber in the ramping period, in real time to correspond to the measured chamber pressure.

6. The substrate processing method of claim 5, wherein the ramping period comprises a period in which speeds of supplying the first and second process gases are different from each other.

7. The substrate processing method of claim 1, wherein the first layers comprise silicon oxide layers, and
wherein the second layers comprise silicon nitride layers.

8. The substrate processing method of claim 1, wherein each of the first and second process steps comprises:
a ramping up period in which a flow rate of a process gas is gradually increased;
a period in which the flow rate of the process gas is constantly maintained; and
a ramping down period in which the flow rate of the process gas is gradually reduced.

9. The substrate processing method of claim 8, wherein the ramping up period of the first process step and the ramping down period of the second process step overlap each other, or
wherein the ramping down period of the first process step and the ramping up period of the second process step overlap each other.

10. The substrate processing method of claim 1, wherein the first and second process steps have different conditions of plasma generation power, and
wherein, when switching between the first and second process steps, the plasma generation power is gradually changed in the ramping period.

11. The substrate processing method of claim 10, wherein a speed of changing the plasma generation power in the ramping period is associated with a speed of changing the flow rate of the first or second process gas in the ramping period.

12. The substrate processing method of claim 10, wherein the ramping period comprises a period in which speeds of changing the plasma generation power are different from each other.

13. The substrate processing method of claim 1, wherein the switching between the first and second process steps comprises:
detecting an end point of one of the first and second process steps;
gradually reducing a flow rate of a process gas used for a process step, the end point of which is detected, while gradually increasing a flow rate of a process gas used for a process step other than the process step, the end point of which is detected; and
maintaining the flow rate of the process gas used for the process step other than the process step, the end point of which is detected, at a set value at a point of time when supply of the process gas used for the process step, the end point of which is detected, is cut off.

14. The substrate processing method of claim 13, wherein the detecting of the end point comprises detecting the end point by analyzing by-products of etching produced during the process step by using an optical emission spectroscope connected to the substrate processing apparatus.

15. A substrate processing apparatus for processing a substrate comprising a multilayer formed by alternately and repeatedly depositing first and second layers of different materials, the substrate processing apparatus comprising:
a chamber having an internal space where plasma is generated, and comprising a substrate supporter in the internal space to support the substrate;
a gas supplier for supplying a first process gas for etching the first layers, and a second process gas for etching the second layers, to the substrate;
a high-frequency power source for applying high-frequency power into the chamber to excite the first or second process gas into plasma; and
a controller for controlling flow rates of the first and second process gases,
wherein the controller controls the flow rates of the first and second process gases to be gradually changed in a ramping period in which switching occurs between a first process step for etching a first layer and a second process step for etching a second layer.

16. The substrate processing apparatus of claim 15, further comprising an end point detector for detecting an end point of a process step by analyzing by-products of etching produced in the internal space.

17. The substrate processing apparatus of claim 15, further comprising a pressure sensor for measuring a pressure inside the chamber,
wherein the controller receives the measured pressure inside the chamber from the pressure sensor in real time, and controls the flow rates of the first and second process gases in the ramping period in real time based on the pressure inside the chamber.

18. The substrate processing apparatus of claim 17, wherein the controller controls plasma generation power to be gradually changed between the first and second process steps in the ramping period.

19. The substrate processing apparatus of claim 18, wherein the controller controls the plasma generation power in real time in association with changes in flow rates of the first and second process gases.

20. A substrate processing apparatus for processing a substrate comprising a multilayer formed by alternately and repeatedly depositing first and second layers of different materials, the substrate processing apparatus comprising:
a chamber having an internal space where plasma is generated, and comprising a substrate supporter in the internal space to support the substrate;
a gas supplier for supplying a first process gas for etching the first layers, and a second process gas for etching the second layers, to the substrate;
a high-frequency power source for applying high-frequency power into the chamber to excite the first or second process gas into plasma;
an end point detector for detecting an end point of a process step by analyzing by-products of etching produced in the chamber;
a vent line connected to a vent hole provided in a portion of the chamber to discharge internal gas, and having an automatic pressure controller valve and a pressure sensor mounted thereon; and
a controller for receiving a measured chamber pressure from the pressure sensor in real time in a ramping period in which switching occurs between a first process step for etching a first layer and a second process step for etching a second layer, controlling flow rates of the first and second process gases in the ramping period in real time based on the chamber pressure, and controlling plasma generation power to be gradually changed between the first and second process steps in real time in association with changes in flow rates of the first and second process gases in the ramping period.
